(19) United States
(12) Patent Application Publication
(10) Pub. No.: US 2021/0148960 A1
(43) Pub. Date: May 20, 2021

(54) Electromagnetic Field Visualization Systems, Kits, and Methods

(71) Applicant: The Florida State University Research Foundation, Inc., Tallahassee, FL (US)

(72) Inventors: Zachary W. Mercer, Tallahassee, FL (US); Jeffrey Whalen, Tallahassee, FL (US); Theo Siegrist, Tallahassee, FL (US)

(21) Appl. No.: 17/097,339

(22) Filed: Nov. 13, 2020

Related U.S. Application Data
(60) Provisional application No. 62/935,195, filed on Nov. 14, 2019.

(51) Int. Cl. G01R 29/08

(52) U.S. Cl. CPC G01R 29/0892; G06T 19/20; G01R 29/0878

(57) ABSTRACT

Systems, kits, and methods for electromagnetic field visualization. The systems and kits may include at least one sensor, a sensor support to which the at least one sensor is mounted, a microprocessor configured to process data from the at least one sensor, and a software platform configured to perform computational enhancement of the data and subsequent augmented reality (AR) visualizations of a magnetic field of an electromagnetic source, such as one or more permanent magnets.

### CROSS-REFERENCE TO RELATED APPLICATIONS

This application claims priority to U.S. Provisional Patent Application No. 62/935,195, filed Nov. 14, 2019, which is incorporated herein by reference.

### STATEMENT REGARDING FEDERALLY SPONSORED RESEARCH AND DEVELOPMENT

This invention was made with government support under contract DMR-1644779 awarded by the National Science Foundation. The government has certain rights in the invention.

### BACKGROUND

Augmented reality (AR) devices that are currently used for “viewing” magnetic fields usually either provide only a numerical value hologram, or the magnetic fields are purely simulations that have been modeled in advance based on an object's geometry, surface field strength, and polarity.

Other more rudimentary existing methods involve using traditional two-dimensional (2D) magnetic field viewing films.

There are currently no acceptable ways to visualize electromagnetic fields in three dimensions easily, despite the fact that the characteristics and underlying physics of magnetic fields are well understood and established in both the research and commercial sectors.

The only way to observe magnetic fields directly is to overlay them in 2D images, as commonly seen in teaching textbooks. Visualization of magnetic fields in real-time and three-dimensions (3D) has not been developed. Crude 2D qualitative magnetic field visualization can be achieved using magnetic viewing films, but physical contact with the magnet is required and the 3D nature of the field is difficult and sometimes impossible to discern.

The need for superior 3D visualization of magnetic fields is present in many applications including, but not limited to, research and development, electrical engineering, education, threat reduction, environmental health and safety, or a combination thereof. Across many venues and applications, the lack of a natural ability to “see and sense” magnetism presents a wide spectrum of risks and potential consequences.

Assumptions about magnetic field characteristics that are based on simple and traditional single-point field measurements using gaussmeters are susceptible to error, and the cascading risks associated with those errors.

For example, large electric motors, heating, ventilation, and air conditioning (HVAC) units, and other industrial equipment emit substantial electromagnetic fields that can disrupt other electronic devices and signals, which can result in partial or complete failure of processes, which can sometimes be critical.

Other applications that face the foregoing need include electric ship designers (e.g., government entities, specifically the U.S. Navy), aircraft manufacturers (e.g., electric motors for flaps, etc.), automotive industries (e.g., electric and hybrid cars), wind turbine technology developers and manufacturers, electric motor manufacturers, etc., and, in general, any entity that has products or services that rely on magnetic fields to function (e.g., hospital MRI systems, NMR research systems, etc.).

Of equal concern is the insufficient education of students (i.e., the future workforce) about magnetic fields, which is caused at least in part by the fact that the students are unable to understand and see clearly how magnetic fields behave around a magnetic source. If students were able to visualize these magnetic fields and the visualization was integrated with its environment, these problems could be addressed intuitively and/or more quickly, if not avoided altogether.

There remains a need for systems and methods that address one or more of the foregoing needs or disadvantages.

### BRIEF SUMMARY

The systems, kits, and methods herein address one or more of the foregoing disadvantages by integrating, in some embodiments, the fundamental physics of magnetism with magnetic sensing and visualization software technology. The systems herein may create more impacting and informative experiences using 3D interactive visualizations of a magnetic field in relation to their environments by combining, in some embodiments, the sensitive and small magnetometer sensors currently commercially available with modern camera vision technologies.

In some embodiments, the systems, kits, or methods herein can display magnetic field lines that can be calculated, simulated/computationally enhanced, and/or projected around an electromagnetic source in an AR visualization platform, while retaining all of the 3D information of the magnetic field with respect to its environment. The visualizations can be dynamic with field strength and polarity direction quantified and shown in real-time.

In one aspect, systems are provided. In some embodiments, the systems include at least one sensor configured to gather data on (i) a relative position of the at least one sensor in space, (ii)(a) a direction and/or (b) a magnitude of a magnetic field detectible from the relative position, or (iii) a combination thereof; a sensor support to which the at least one sensor is mounted; a microprocessor configured to process data from the at least one sensor; and a software platform configured to perform computational enhancement of the data and subsequent AR visualizations of the magnetic field.

In some embodiments, the systems include at least one sensor configured to gather data on (i) a relative position of the at least one sensor in space, (ii)(a) a direction and/or (b) a magnitude of a magnetic field detectible from the relative position, or (iii) a combination thereof; a sensor support to which the at least one sensor is mounted; a microprocessor configured to process data from the at least one sensor; a software platform configured to perform computational enhancement of the data and subsequent AR visualizations of the magnetic field; and an AR device or a visual flat screen; wherein the software platform is configured to construct a 3D image of the magnetic field, and wherein the software platform is configured to (i) overlay the 3D image of the magnetic field on a source for which the electromagnetic field is visualized, and (ii) display the 3D image and the source on the AR device or the visual flat screen.

In a further aspect, a kit of parts is provided. In some embodiments, the kit of parts includes at least one sensor as described herein; a microprocessor configured to process data from the at least one sensor; a software platform configured to perform computational enhancement of the data and subsequent AR visualizations of the magnetic field; and an electromagnetic source, such as one or more permanent magnets. In some embodiments, the kits also include an AR device or a visual flat screen. In some embodiments, the kits also include a sensor support.

In another aspect, methods are provided. In some embodiments, the methods include providing a system as described herein; positioning one or more permanent magnets in a viewing field of at least one sensor; and displaying a sensor-derived and/or computationally-derived magnetic field while maintaining continuous alignment with the one or more permanent magnets.

In some embodiments, the methods include providing a system as described herein; positioning two or more permanent magnets in a viewing field of the at least one sensor at a first location; and positioning the two permanent magnets in the viewing field of the at least one sensor at a second location, wherein the two permanent magnets are closer to each other at the second location compared to the first location; and observing one or more resulting attractive and/or repulsive magnetic field characteristics.

Additional aspects will be set forth in part in the description which follows, and in part will be obvious from the description, or may be learned by practice of the aspects described herein. The advantages described herein will be realized and attained by means of the elements and combinations particularly pointed out in the appended claims. It is to be understood that both the foregoing general description and the following detailed description are exemplary and explanatory and are not restrictive.

### BRIEF DESCRIPTION OF THE DRAWINGS

FIG. 1 depicts an embodiment of a system described herein.

FIG. 2 depicts an embodiment of a method described herein.

### DETAILED DESCRIPTION

In some embodiments, the systems and methods described herein use AR in conjunction with electromagnetic, spatial and/or acceleration rate sensor-derived data that may be further supported and enhanced by electrodynamic computational modeling to produce a 3D visualization of real-time electromagnetic fields for a user.

### Systems

In some embodiments, the systems herein include at least one sensor. The at least one sensor of the systems herein may be configured to gather data on (i) a relative position of the at least one sensor in space, (ii)(a) a direction and/or (b) a magnitude of a magnetic field detectible from the relative position, or (iii) a combination thereof.

The magnetic field detectible from the relative position may be generated by a source. The term “source” and the phrase “electromagnetic source”, as used herein, refer to any material, object, etc. that creates an electromagnetic field that is detectible with the systems and methods described herein.

Generally, any sensor known in the art may be used in the systems and methods described herein. The systems may include one sensor, two sensors, three sensors, four sensors, etc. When more than one sensor is included in the systems described herein, the sensors may include different types of sensors. For example, the at least one sensor may include a magnetometer, an orientation sensor (e.g., a gyroscope, accelerometer, etc.), a distance sensor, or any combination thereof.

The “magnetometer” may include any sensor capable of gathering data on an electromagnetic field's direction and/or magnitude. One or more magnetometers, for example, may be used to capture raw 3D data at or near an electromagnetic source.

The “orientation sensor” may include any sensor that is capable of determining roll, pitch, and yaw of a sensor or sensor module with respect to a source, which can permit the directional data from a magnetometer to be made relative to the sensor or sensor module and thus the source.

The “distance sensor” may include any sensor capable of detecting a sensor's distance from an electromagnetic source. Non-limiting examples of distance sensors include an infrared sensor, an ultrasonic sensor, a potentiometer with a string, etc.

In some embodiments, the at least one sensor includes a gyroscope, an accelerometer, or a combination thereof. In some embodiments, the at least one sensor includes a magnetometer, a hall sensor, or a combination thereof. In some embodiments, the at least one sensor includes a gyroscope, an accelerometer, a magnetometer, a hall sensor, or a combination thereof. In some embodiments, the at least one sensor includes a gyroscope, an accelerometer, a magnetometer, a hall sensor, a distance sensor, or a combination thereof.

In some embodiments, the systems described herein include at least three sensors of different types. For example, the systems described herein may include (i) a magnetometer, (ii) an orientation sensor (e.g., a gyroscope, an accelerometer, or a combination thereof), and (iii) a distance sensor (infrared, ultrasonic, potentiometer w/a string, there are many options) to detect the module's distance from the source.

The at least one sensor of the systems described herein generally may be arranged at any location relative to a source. In some embodiments, the systems include a sensor support to which at least one sensor is mounted. A sensor may be fixably or detachably mounted in any manner to a sensor support. The one or more sensors may be mounted to a rod (e.g., an end of a rod), mounted to a scaffold system, and/or include arbitrarily user-positioned sensor(s). A (i) rod, scaffold system, and/or housing and at least one sensor that is mounted to the rod, scaffold system, and/or housing and/or (ii) an arrangement of sensor(s) may be referred to herein as a “module” or “sensor module”.

In some embodiments, the systems described herein include a microprocessor configured to process data from the at least one sensor. A microprocessor may process data from at least one sensor into a usable form for a software platform.

For example, data from at least one sensor may be processed through an algorithm to interpolate what a magnetic field may look like. The microprocessor may be able to read in data, and apply it to the algorithm and then output an object. Creating a unique object may require many triangles with user defined vertices to be first connected (e.g., a mesh), and then painted over. This mesh should be able to cover all spots that were output through the algorithm in a fluid manner to produce the holograms (e.g., 3D images).

In some embodiments, the systems include a software platform configured to perform computational enhancement of the data and subsequent AR visualizations of the magnetic field. For example, the systems may include a microprocessor that processes data from at least one sensor into a usable form for the software platform, and the software platform may then perform computational enhancement and subsequent AR visualizations.

In some embodiments, the software constructs a 3D image of magnetic fields, as described herein. The 3D image may display different information in one or more distinguishing ways. For example, the 3D image may show the field strength and/or flux density as color gradients, vectors of varying dimensions and/or other traditional methods of intuitive qualitative and quantitative visualizations. The 3D image may be referred to herein as a “hologram”.

In some embodiments, the systems also include a visual flat screen or AR device, such as a wearable AR device. The wearable AR device may include an AR headset. The visual flat screen may include a smartphone or any other display device. The software platform of the systems may work in conjunction with an AR device or visual flat screen so that the 3D magnetic fields are overlayed, in some embodiments, on the source for which the electromagnetic fields are to be visualized and then displayed on a user worn AR device or a visual flat screen.

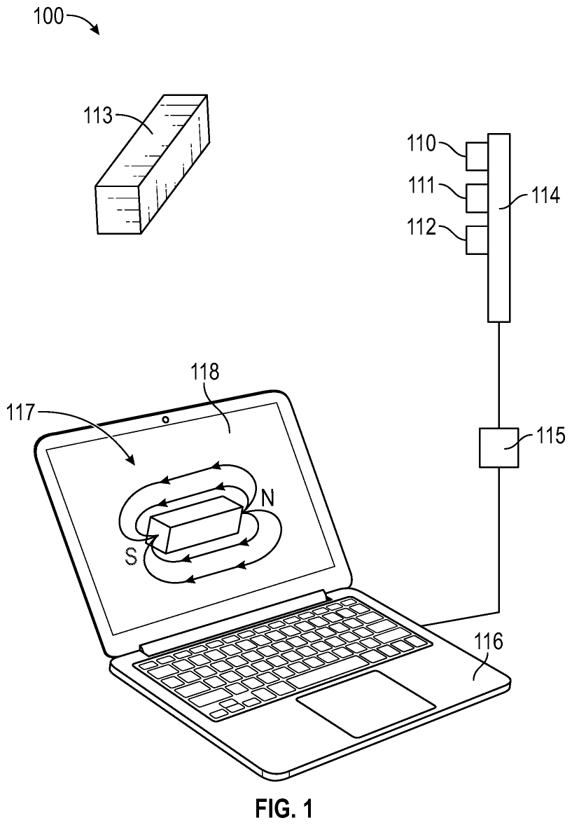

An embodiment of a system described herein is depicted at FIG. 1. The system 100 of FIG. 1 includes three sensors (110, 111, 112) mounted to a rod 114. The system 100 includes a microprocessor 115 in communication with the sensors (110, 111, 112) and a computer 116 that includes a software platform configured to perform computational enhancement of the data gathered from the three sensors (110, 111, 112) and subsequent AR visualizations of a magnetic field. The system 100 also includes a visual flat screen 118 that displays a visualization 117 of the magnetic field of the permanent magnet 113, which is the source in the embodiment of the system depicted at FIG. 1.

In some embodiments, the systems also include one or more permanent magnets. The one or more permanent magnets may be configured for use in research instrumentation, electric motors, or a combination thereof. The one or more permanent magnets may (i) be irregularly shaped, (ii) have irregular polarities, or (iii) a combination thereof.

### Kits

Kits of parts also are provided herein. In some embodiments, the kits include a sensor as described herein, a microprocessor as described herein, and a software platform as described herein. In some embodiments, the kits include a sensor as described herein, a microprocessor as described herein, a software platform as described herein, and an electromagnetic source. In some embodiments, the kits include a sensor as described herein, a microprocessor as described herein, a software platform as described herein, an electromagnetic source, and an AR device or a visual flat screen. In some embodiments, the kits include a sensor as described herein, a microprocessor as described herein, a software platform as described herein, an electromagnetic source, and a sensor support. In some embodiments, the kits include a sensor as described herein, a microprocessor as described herein, a software platform as described herein, an electromagnetic source, an AR device or a visual flat screen, and a sensor support. The kit of parts also may include a set of instructions for operating one or more components of the kit.

The electromagnetic source that may be included in the kits can include one or more permanent magnets, as described herein. The kits may include one permanent magnet, two permanent magnets, etc.

In some embodiments, the kit may be suitable for educational purposes, and includes the AR software platform for installation on a user's computer and a set of permanent magnets so that a user (e.g., learner) can position one or more of the permanent magnets in the viewing field of their computer's camera and have sensor-derived and/or computationally-derived magnetic fields be displayed while maintaining continuous alignment with the permanent magnet(s). Additionally or alternatively, a kit may allow a user to bring two permanent magnets into the viewing field and observe the resulting attractive and/or repulsive magnetic field characteristics when the magnets are brought into close proximity to each other.

### Methods

Also provided herein are methods, including methods of viewing a magnetic field.

The methods may include providing a system as described herein; positioning a source, such as one or more permanent magnets, in a viewing field of at least one sensor of the system; and displaying a sensor-derived and/or computationally-derived magnetic field while maintaining continuous alignment with the source, such as one or more permanent magnets. For example, the embodiment of the system depicted at FIG. 1 may be provided, the permanent magnet 113 may be positioned in a viewing field of the three sensors (110, 111, 112), and a sensor-derived and/or computationally-derived magnetic field may be displayed while maintaining continuous alignment of the sensors (110, 111, 112) with the permanent magnet 113.

The methods may include providing a system as described herein; positioning a first part and a second part of a source, such as two permanent magnets, in a viewing field of at least one sensor at a first location; and positioning the first part and the second part of the source in the viewing field of the at least one sensor at a second location, wherein the first part and second part of the source are closer to each other at the second location compared to the first location; and observing one or more resulting attractive and/or repulsive magnetic field characteristics.

In some embodiments, the provided systems include an AR device or a visual flat screen, and the displaying of the sensor-derived and/or computationally-derived magnetic field includes overlaying an image of the sensor-derived and/or computationally-derived magnetic field on the source, such as one or more permanent magnets, and (ii) displaying the image of the sensor-derived and/or computationally-derived magnetic field and the source on the AR device or the visual flat screen.

Any of the systems described herein may be used in the methods described herein. In some embodiments, the methods include providing a system that includes a module. The module may include several sensors and has least two buttons. In some embodiments, the system includes at least three sensor types: a magnetometer to gather data on the electromagnetic field's direction and magnitude, an orientation sensor (gyroscope/accelerometer) to determine the module's roll, pitch, and/or yaw with respect to the source (so the directional data from the magnetometer can be made relative to the module and thus the source), and a distance sensor (infrared, ultrasonic, potentiometer w/a string, etc.) to detect the module's distance from the source. The first button of the module may take a “snapshot” of the sensors' data and record it into a history array. The second button of the module may send the history array of data to the microprocessor. The microprocessor may receive the data by any known technique, e.g., wirelessly or a direct plug into the microprocessor.

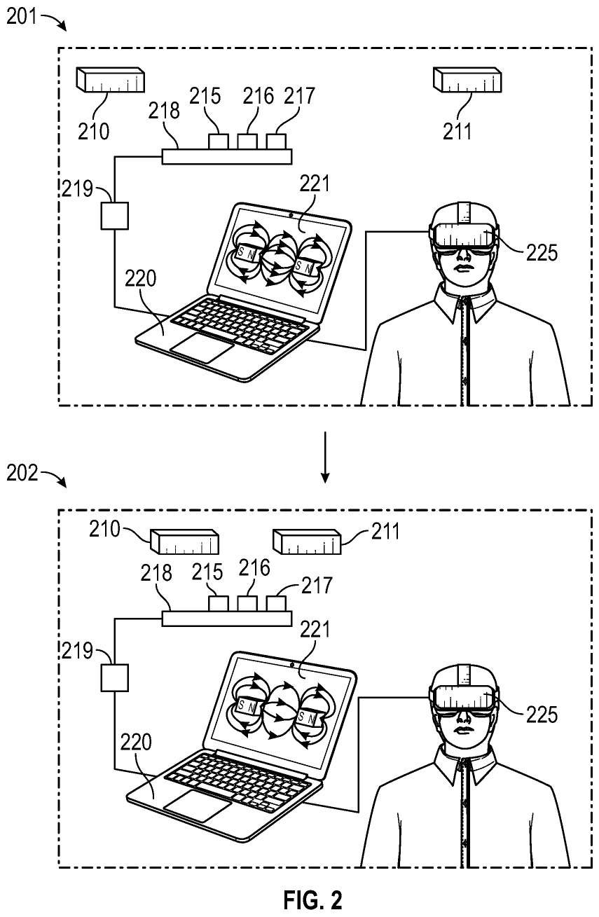

An embodiment of a method is depicted at FIG. 2. In the method depicted at FIG. 2, two permanent magnets (210, 211) are arranged at a first position 201, and then a second position 202. At the section position 202, the two permanent magnets (210, 211) are closer to each other compared to the first position 201. At the two positions (201, 202) and/or while the two permanent magnets (210, 211) are moved from the first position 201 to the second position 202, a 3D image of the magnetic field is depicted in real time (i) on the visual flat screen 221 of the computer 220 and/or by the AR device 225. The system used in the embodiment of the method depicted at FIG. 2 includes three sensors: a magnetometer 215, an orientation sensor 216, and a distance sensor 217. The three sensors (215, 216, 217) are fixably mounted to a rod 218, which is an embodiment of a sensor support. The system of FIG. 2 also includes a microprocessor 219 and a computer 220 that includes a software platform configured to perform computational enhancement of the data gathered from the three sensors (215, 216, 217) and subsequent AR visualizations of a magnetic field. The computer may include a camera that takes the images of the permanent magnets onto which the AR visualization is imposed. Alternatively, a separate camera may be used. Although not shown in FIG. 2, the visualization may include other data, such as numbers, that indicate other parameters described herein, such as magnetic field strength, flux density, etc.

A source, as described herein, produces an electromagnetic field, and, in the methods described herein, a target image may be placed onto the source. The image may have well defined shapes, lines, and/or colors. The image may not be a pattern but may have a random appearance that makes it unique and easily distinguishable by a camera or vision system.

In some embodiments, the systems described herein “lock” the holograms to a target (e.g., a source) rather than the background, and have the advantage of using sensor-derived data and computational enhancement to produce 3D AR visualizations that are realistic and flexible to work with any source, including at least one permanent magnet or electromagnet. This may allow for the use of the systems and methods described herein in a number of applications, such as education and/or health and safety certification where existing technologies fail to provide the same level of information and/or fail to have flexibility to provide visualizations beyond a specified set of sources, e.g., magnet(s).

This may allow for the intuitive visualization of an otherwise invisible phenomenon and thus a brand new approach to understanding and observing electromagnetic fields. In some embodiments, the system is used for 3D visualization of complex permanent magnets and electromagnets that have irregular shapes and/or polarities for any number of purposes, including higher level education and research.

For educational purposes, the systems and methods described herein can permit users (e.g., learners) to observe magnetic fields, and how they “lock” on to the source based on its polarity by moving the source around in the AR visualization and having the magnetic field lines be continuously correctly displayed coupled to the source's orientation.

For environmental health and safety purposes, embodiments of the AR visualization systems and methods for magnetic fields provided herein can allow a user to observe fringe and stray magnetic fields that are typically present around large magnet systems, where interferences can pose risks, such as for workers with implanted pacemakers that should not be subjected to more than a field strength of 5 Gauss. Furthermore, the safe placement of tools made from magnetic steel can be guided by the systems provided herein, thereby reducing the risk of dangerous acceleration of tools towards a magnet.

In the descriptions provided herein, the terms “includes,” “is,” “containing,” “having,” and “comprises” are used in an open-ended fashion, and thus should be interpreted to mean “including, but not limited to.” When methods, kits, and systems are claimed or described in terms of “comprising” various components or steps, the methods, kits, and systems can also “consist essentially of” or “consist of” the various components or steps, unless stated otherwise.

The terms “a,” “an,” and “the” are intended to include plural alternatives, e.g., at least one. For instance, the disclosure of “a sensor,” “a microprocessor,” and the like, is meant to encompass one, or mixtures or combinations of more than one sensor, microprocessor, and the like, unless otherwise specified.

The processes described herein may be carried out or performed in any order as desired in various implementations. Additionally, in certain implementations, at least a portion of the processes may be carried out in parallel. Furthermore, in certain implementations, less than or more than the processes described may be performed.

Many modifications and other implementations of the disclosure set forth herein will be apparent having the benefit of the teachings presented in the foregoing descriptions and the associated drawings. Therefore, it is to be understood that the disclosure is not to be limited to the specific implementations disclosed and that modifications and other implementations are intended to be included within the scope of the appended claims

### EXAMPLES

The present invention is further illustrated by the following examples, which are not to be construed in any way as imposing limitations upon the scope thereof. On the contrary, it is to be clearly understood that resort may be had to various other aspects, embodiments, modifications, and equivalents thereof which, after reading the description herein, may suggest themselves to one of ordinary skill in the art without departing from the spirit of the present invention or the scope of the appended claims. Thus, other aspects of this invention will be apparent to those skilled in the art from consideration of the specification and practice of the invention disclosed herein.

### Example 1—Measurement of Magnetic Field

A proof of concept system can demonstrate the sensor detection and measurement of an external magnetic field which is then used to create user-facing holograms indicating the magnitude and polarity of the magnetic field.

Interpolation algorithms are used in this example to significantly enhance the visualizations by utilizing the real-time data from sensors and basic physical laws of magnetic field characteristics such as flux loop closure and field strength diminishment as a function of increasing proximity.

With additional physical sensors to give the relative location of the magnetic field sensors with respect to the electromagnetic field's source, it may be possible to display a 3-dimensional visual around the source of the magnetic field that can be dynamically viewed from any perspective by the user.

This technology provides a safe and effective method to visualize magnetic fields for government, educational, and research applications.

We claim:

1. A system comprising:
at least one sensor configured to gather data on—
(i) a relative position of the at least one sensor in space,
(ii) (a) a direction and/or (b) a magnitude of a magnetic field detectible from the relative position, or
(iii) a combination thereof;
a sensor support to which the at least one sensor is mounted;
a microprocessor configured to process data from the at least one sensor; and
a software platform configured to perform computational enhancement of the data and subsequent augmented reality (AR) visualizations of the magnetic field.

2. The system of claim 1, wherein the software platform is configured to construct a three dimensional (3D) image of the magnetic field.

3. The system of claim 2, wherein the 3D image displays a field strength, a flux density, or both the field strength and the flux density as—
(i) a color gradient,
(ii) one or more vectors of varying dimensions, or
(iii) a combination thereof.

4. The system of claim 2, further comprising an AR device or a visual flat screen,
wherein the software platform is configured to (i) overlay the 3D image of the magnetic field on a source for which the electromagnetic field is visualized, and (ii) display the 3D image and the source on one or both of the AR device and the visual flat screen.

5. The system of claim 4, wherein the AR device is a wearable AR device.

6. The system of claim 1, wherein the sensor support comprises a rod, a scaffold system, a housing, or a combination thereof.

7. The system of claim 1, wherein the at least one sensor is configured to gather data on (i) the relative position of the at least one sensor in space, and (ii) the direction and the magnitude of the magnetic field detectible from the relative position.

8. The system of claim 1, wherein the at least one sensor comprises a gyroscope, an accelerometer, or a combination thereof.

9. The system of claim 1, wherein the sensor comprises a magnetometer, a hall sensor, or a combination thereof.

10. The system of claim 1, wherein the system further comprises one or more permanent magnets as a source of the magnetic field.

11. A method of viewing a magnetic field, the method comprising:
providing a system comprising—
at least one sensor configured to gather data on (i) a relative position of the at least one sensor in space, (ii)(a) a direction and/or (b) a magnitude of a magnetic field detectible from the relative position, or (iii) a combination thereof,
a sensor support to which the at least one sensor is mounted,
a microprocessor configured to process data from the at least one sensor,
a software platform configured to perform computational enhancement of the data and subsequent augmented reality (AR) visualizations of the magnetic field, and
one or more permanent magnets;
positioning the one or more permanent magnets in a viewing field of the at least one sensor; and
displaying a sensor-derived and/or computationally-derived magnetic field while maintaining continuous alignment with the one or more permanent magnets.

12. The method of claim 11, wherein the one or more permanent magnets are configured for use in research instrumentation, electric motors, or a combination thereof.

13. The method of claim 11, wherein the one or more permanent magnets (i) are irregularly shaped, (ii) have irregular polarities, or (iii) a combination thereof.

14. The method of claim 11, wherein the system further comprises an AR device or a visual flat screen, and the displaying of the sensor-derived and/or computationally-derived magnetic field comprises overlaying an image of the sensor-derived and/or computationally-derived magnetic field on the one or more permanent magnets, and (ii) displaying the image of the sensor-derived and/or computationally-derived magnetic field and the one or more permanent magnets on one or both of the AR device and the visual flat screen.

15. A method of viewing a magnetic field, the method comprising:
providing a system comprising—
at least one sensor configured to gather data on (i) a relative position of the at least one sensor in space, (ii)(a) a direction and/or (b) a magnitude of a magnetic field detectible from the relative position, or (iii) a combination thereof,
a sensor support to which the at least one sensor is mounted,
a microprocessor configured to process data from the at least one sensor,
a software platform configured to perform computational enhancement of the data and subsequent augmented reality (AR) visualizations of the magnetic field, and
one or more permanent magnets;
positioning two of the one or more permanent magnets in a viewing field of the at least one sensor at a first location; and
positioning the two permanent magnets in the viewing field of the at least one sensor at a second location, wherein the two permanent magnets are closer to each other at the second location compared to the first location; and
observing one or more resulting attractive and/or repulsive magnetic field characteristics.

16. The method of claim 15, wherein the one or more permanent magnets are configured for use in research instrumentation, electric motors, or a combination thereof.

17. The method of claim 15, wherein the one or more permanent magnets (i) are irregularly shaped, (ii) have irregular polarities, or (iii) a combination thereof.

18. A kit of parts comprising:
at least one sensor configured to gather data on—
(i) a relative position of the at least one sensor in space,
(ii)(a) a direction and/or (b) a magnitude of a magnetic field detectible from the relative position, or
(iii) a combination thereof,
a microprocessor configured to process data from the at least one sensor,
a software platform configured to perform computational enhancement of the data and subsequent augmented reality (AR) visualizations of the magnetic field, and
one or more permanent magnets;
wherein the software platform is configured to construct a three dimensional (3D) image of the magnetic field, and
wherein the software platform is configured to (i) overlay the 3D image of the magnetic field on the one or more permanent magnets for which the electromagnetic field is visualized, and (ii) display the 3D image and the one or more permanent magnets.

19. The kit of claim 18, further comprising an AR device or a visual flat screen.

20. The kit of claim 18, further comprising a sensor support.
